(19) United States
(12) Patent Application Publication
(10) Pub. No.: US 2017/0012604 A1
(43) Pub. Date: Jan. 12, 2017

(54) VIBRATOR AND MANUFACTURING METHOD THEREFOR, OSCILLATOR, ELECTRONIC DEVICE, AND MOVABLE BODY

(71) Applicant: SEIKO EPSON CORPORATION, Tokyo (JP)

(72) Inventor: Takahiko YOSHIZAWA, Sakata-shi (JP)

(73) Assignee: SEIKO EPSON CORPORATION, Tokyo (JP)

(21) Appl. No.: 15/200,775

(22) Filed: Jul. 1, 2016

(30) Foreign Application Priority Data
Jul. 8, 2015 (JP) 2015-136695

(51) Int. Cl. H03H 9/17; H03B 5/32; H01L 41/053; H01L 41/311; H01L 41/047; H01L 41/18

(52) U.S. Cl. CPC H03H 9/17; H01L 41/0477; H01L 41/18; H01L 41/053; H01L 41/311; H03B 5/32

(57) ABSTRACT

A vibrator includes a substrate, an electrode located on the substrate, a vibrating piece, an interconnect that includes a first joining portion surrounding the electrode on the substrate and is connected to the vibrating piece and electrically connected to the electrode, and a lid portion that has an opening for exposing the electrode and is joined to the first joining portion.

### BACKGROUND

1. Technical Field

The present invention relates to a vibrator and a manufacturing method therefor. Moreover, the invention relates to an oscillator, an electronic device, a movable body, and the like in which such a vibrator is used.

2. Related Art

For example, in a vibrator including a piezoelectric vibrating element that vibrates by applying an alternating voltage, the piezoelectric vibrating element is sealed in a sealing structure in a vacuum state or in a state in which inert gas is enclosed. Also, in a vibrator that does not require a vacuum state or the like, the vibrating element is sealed in a sealing structure, in order to prevent the influence of dust, moisture, and the like. In such cases, the joining reliability of a lid portion that constitutes the sealing structure is a problem.

As a related technique, a driving portion 15 provided in a vibrating arm 14 of paired vibrating arms 13 and 14 is shown in FIG. 1 of JP-A-2015-46807 (paras. 0048-0053, FIG. 1). The driving portion 15 has a structure in which a first electrode 16, an insulating oriented film 17, a piezoelectric film 18, and a second electrode 19 are stacked in this order. A lead-out electrode 16a led out from the first electrode 16 is connected to an electrode pad 16b provided on a main surface 10a of a substrate 10 via a base portion 12 and a fixing portion 11. Also, a lead-out electrode 19a led out from the second electrode 19 is connected to an electrode pad 19b provided on the main surface 10a of the substrate 10 via the base portion 12 and the fixing portion 11.

A lid (lid body) 22 of the package is placed on and fixed to the main surface 10a of the substrate 10, which serves as a package base, so as to cover the fixing portion 11, the base portion 12, and the vibrating arms 13 and 14. Because electrode pads 16b and 19b are located outside the lid 22, the structure is such that the lid 22 straddles the lead-out electrodes 16a and 19a. Because the lead-out electrodes 16a and 19a are provided on the main surface 10a of the substrate 10, there is concern that a level difference will occur on the main surface 10a of the substrate 10 due to the lead-out electrodes 16a and 19a, and the joining reliability of the lid 22 will decrease.

Some aspects according to the invention relate to providing a vibrator in which the joining reliability of the lid portion is improved by reducing the influence of a level difference caused by interconnects on the joining reliability of the lid portion.

Also, some aspects according to the invention relates to providing an oscillator, an electronic device, a movable body, and the like in which such a vibrator is used.

### SUMMARY

A vibrator according to a first aspect of the invention includes, a substrate, an electrode located on the substrate, a vibrating piece, an interconnect that includes a first joining portion surrounding the electrode on the substrate and is connected to the vibrating piece and electrically connected to the electrode, and a lid portion that has an opening for exposing the electrode and is joined to the first joining portion.

According to the first aspect of the invention, the interconnect that includes the first joining portion surrounding the electrode is located on the substrate and the lid portion is joined to the first joining portion, and thus the influence of a level difference caused by the interconnect on the joining reliability of the lid portion can be reduced and the joining reliability of the lid portion can be improved.

Here, the vibrator may further include a conductive film that is located on least at the first joint portion. For example, if, in addition to the above-described electrode and interconnect, the vibrator further includes a second electrode, a second interconnect that includes a second joining portion surrounding the second electrode, and a second conductive film located on at least the second joining portion, the joining reliability of the lid portion can be improved by making the heights of the first and second joining portions equal to each other with the above-described conductive film.

Also, the vibrator may further include a second joining portion that is located on the substrate so as to surround the vibrating piece and the electrode at a distance from the vibrating piece and the electrode, and to which the lid portion is connected. Accordingly, the lid portion is joined to the first joining portion and the second joining portion, and thus the vibrating piece can be sealed.

In this case, the vibrator may further include a joining film located on at least the first joining portion and the second joining portion, and the lid portion may be joined to the first joining portion and the second joining portion via at least the joining film. The joining reliability of the lid portion can be further increased by providing the joining film.

A vibrator according to a second aspect of the invention includes a substrate, a first electrode and a second electrode that are located on the substrate, a vibrating piece, a first interconnect that includes a first joining portion surrounding the first electrode on the substrate and is connected to the vibrating piece and electrically connected to the first electrode, a second interconnect that includes a second joining portion surrounding the second electrode on the substrate and is connected to the vibrating piece and electrically connected to the second electrode, a third joining portion that is located on the substrate so as to surround the vibrating piece and the first and second electrodes at a distance from the vibrating piece and the first and second electrodes, and a lid portion that has an opening for exposing the first and second electrodes and is joined to the first to third joining portions.

According to the second aspect of the invention, the first interconnect includes the first joining portion surrounding the first electrode, the second interconnect includes the second joining portion surrounding the second electrode, and the third joining portion that surrounds the vibrating piece and the first and second electrodes are provided, and the lid portion is joined to the first to third joining portions, and thus the influence of a level difference caused by the interconnects on the joining reliability of the lid portion on can be reduced and the joining reliability of the lid portion can be improved.

A vibrator according to a third aspect of the invention includes a substrate, a first electrode and a second electrode that are located on the substrate, a vibrating piece, a first interconnect that includes a first joining portion surrounding the first electrode on the substrate and is connected to the vibrating piece and electrically connected to the first electrode, a second interconnect that includes a second joining portion surrounding the second electrode on the substrate and is electrically connected to the second electrode, a third joining portion that is located on the substrate so as to surround the vibrating piece and the first and second electrodes at a distance from the vibrating piece and the first and second electrodes, a conductive film that is connected to the vibrating piece and electrically connected to the second interconnect, and a lid portion that has an opening for exposing the first and second electrodes and is joined to the first to third joining portions.

According to the third aspect of the invention, since the first to third joining portions to which the lid portion is joined can be formed simultaneously, the influence of a level difference caused by the interconnects on the joining reliability of the lid portion can be reduced by making heights of the first to third joining portions equal to each other, and thus the joining reliability of the lid portion can be improved.

A vibrator according to a fourth aspect of the invention includes a substrate, a first electrode and a second electrode that are located on the substrate, a vibrating piece, a first interconnect that includes a first joining portion surrounding the first electrode on the substrate and is connected to the vibrating piece and electrically connected to the first electrode, a second interconnect that includes a second joining portion surrounding the second electrode on the substrate and is electrically connected to the second electrode, a third joining portion that is located on the substrate so as to surround the vibrating piece and the first and second electrodes at a distance from the vibrating piece and the first and second electrodes, a conductive layer that includes a first conductive film located on at least the first joining portion, a second conductive film connected to the vibrating piece and located on at least the second joining portion, a third conductive film located on at least the third joining portion, and a lid portion that has an opening for exposing the first and second electrodes and is joined to the first to third joining portions via at least the conductive layer.

According to the fourth aspect of the invention, since the first to third joining portions to which the lid portion is joined can be formed simultaneously and then the first to third conductive films are formed simultaneously thereon, the influence of a level difference caused by the interconnects on the joining reliability of the lid portion can be reduced by making heights of the first to third conductive films equal to each other, and thus the joining reliability of the lid portion can be improved.

An oscillator according to a fifth aspect of the invention includes any of the above-described vibrators. According to the fifth aspect of the invention, it is possible to provide a stable oscillator having a small change in the oscillation frequency over time, using a vibrator having improved joining reliability of the lid portion that constitutes the sealing structure.

An electronic device and a movable body according to a sixth aspect of the invention include any of the above-described vibrators. According to the sixth aspect of the invention, it is possible to provide an electronic device and a movable body that operate in synchronization with a clock signal having a stable frequency obtained by using the vibrator having improved joining reliability of the lid portion that constitutes the sealing structure.

A method for manufacturing a vibrator according to a seventh aspect of the invention includes (a) forming an electrode on a substrate, (b) forming an interconnect that includes a joining portion surrounding the electrode on the substrate and is electrically connected to the electrode, (c) forming a vibrating piece that is connected to the interconnect, and (d) joining a lid portion that has an opening for exposing the electrode to the joining portion.

According to the seventh aspect of the invention, the interconnect that includes the joining portion surrounding the electrode is formed on the substrate and the lid portion is joined to the joining portion, and thus the influence of a level difference caused by the interconnect provided to connect the vibrating element to an external circuit on the joining reliability of the lid portion can be reduced, and the joining reliability of the lid portion can be improved.

A method for manufacturing a vibrator according to an eighth aspect of the invention includes (a) forming a first electrode and a second electrode on a substrate, (b) forming, on the substrate, a first interconnect that includes a first joining portion surrounding the first electrode and is electrically connected to the first electrode and a second joining portion that surrounds the first and second electrodes at a distance from the first and second electrodes, (c) forming a vibrating piece that is connected to the first interconnect, (d) forming a second interconnect that includes a third joining portion surrounding the second electrode on the substrate and is connected to the vibrating piece and electrically connected to the second electrode, and (e) joining a lid portion that has an opening for exposing the first and second electrodes to the first to third joining portions.

According to the eighth aspect of the invention, by making the thicknesses of the first to third joining portions substantially equal to each other, a level difference caused by the first to third joining portions does not occur, and thus the joining reliability of the lid portion can be improved. Also, a process of flattening the joining film by CMP and reducing the thickness of the joining film by etchback is not required.

A method for manufacturing a vibrator according to a ninth aspect of the invention includes (a) forming a first electrode and a second electrode on a substrate, (b) forming, on the substrate, a first interconnect that includes a first joining portion surrounding the first electrode and is electrically connected to the first electrode, and a second interconnect that includes a second joining portion surrounding the second electrode and is electrically connected to the second electrode, and a third joining portion that surrounds the first and second electrodes at a distance from the first and second electrodes, (c) forming a vibrating piece that is connected to the first interconnect, (d) forming a conductive film that is connected to the vibrating piece and electrically connected to the second interconnect, and (e) joining a lid portion that has an opening for exposing the first and second electrodes to the first to third joining portions.

According to the ninth aspect of the invention, since the first to third joining portions to which the lid portion is connected are formed simultaneously, the heights of the first to third joining portions can be made equal to each other, and the joining reliability of the lid portion can be improved. Also, a process of flattening the joining film by CMP and reducing the thickness of the joining film by etchback is not required.

A method for manufacturing a vibrator according to a tenth aspect of the invention includes (a) forming a first electrode and a second electrode on a substrate, (b) forming, on the substrate, a first interconnect that includes a first joining portion surrounding the first electrode and is electrically connected to the first electrode, a second interconnect that includes a second joining portion surrounding the second electrode and is electrically connected to the second electrode, and a third joining portion that surrounds the first and second electrodes at a distance from the first and second electrodes, (c) forming a vibrating piece that is connected to the first interconnect,(d) forming a conductive layer that includes a first conductive film located on at least the first joining portion, a second conductive film that is connected to the vibrating piece and is located on at least the second joining portion, and a third conductive film located on at least the third joining portion, and (e) joining a lid portion that has an opening for exposing the first and second electrodes to the first to third joining portions via at least the conductive layer.

According to the tenth aspect of the invention, since the first to third conductive films are also formed simultaneously after the first to third joining portions to which the lid portion is connected have been formed simultaneously, the heights of the first to third conductive films can be made equal to each other, and the joining reliability of the lid portion can be improved. Also, a process of flattening the joining film by CMP and reducing the thickness of the joining film by etchback is not required.

### BRIEF DESCRIPTION OF THE DRAWINGS

The invention will be described with reference to the accompanying drawings, wherein like numbers reference like elements.

FIGS. 1A and 1B are diagrams showing a vibrator according to a first embodiment of the invention.

FIGS. 2A to 2G are process diagrams for illustrating a method for manufacturing the vibrator according to the first embodiment of the invention.

FIGS. 3A and 3B are diagrams showing a vibrator according to a second embodiment of the invention.

FIGS. 4A to 4G are process diagrams for illustrating a method for manufacturing the vibrator according to the second embodiment of the invention.

FIGS. 5A and 5B are diagrams showing a vibrator according to a third embodiment of the invention.

FIGS. 6A and 6B are diagrams showing the vibrator according to the third embodiment of the invention.

FIGS. 7A to 7G are process diagrams for illustrating a method for manufacturing the vibrator according to the third embodiment of the invention.

FIGS. 8A to 8G are process diagrams for illustrating a method for manufacturing the vibrator according to the third embodiment of the invention.

FIGS. 9A and 9B are diagrams showing a vibrator according to a fourth embodiment of the invention.

FIGS. 10A to 10I are process diagrams for illustrating a method for manufacturing the vibrator according to the fourth embodiment of the invention.

FIGS. 11A to 11I are process diagrams for illustrating a method for manufacturing the vibrator according to the fourth embodiment of the invention.

FIG. 12 is a circuit diagram showing a configuration example of an oscillator according to an embodiment of the invention.

FIG. 13 is a block diagram showing a first configuration example of an electronic device according to an embodiment of the invention.

FIG. 14 is a block diagram showing a second configuration example of an electronic device according to an embodiment of the invention.

FIG. 15 is a block diagram showing a configuration example of a movable body according to an embodiment of the invention.

### DESCRIPTION OF EXEMPLARY EMBODIMENTS

Hereinafter, embodiments of the invention will be described in detail with reference to the drawings. Note that the same reference signs are given to the same constituent elements, and redundant description is omitted. First Embodiment

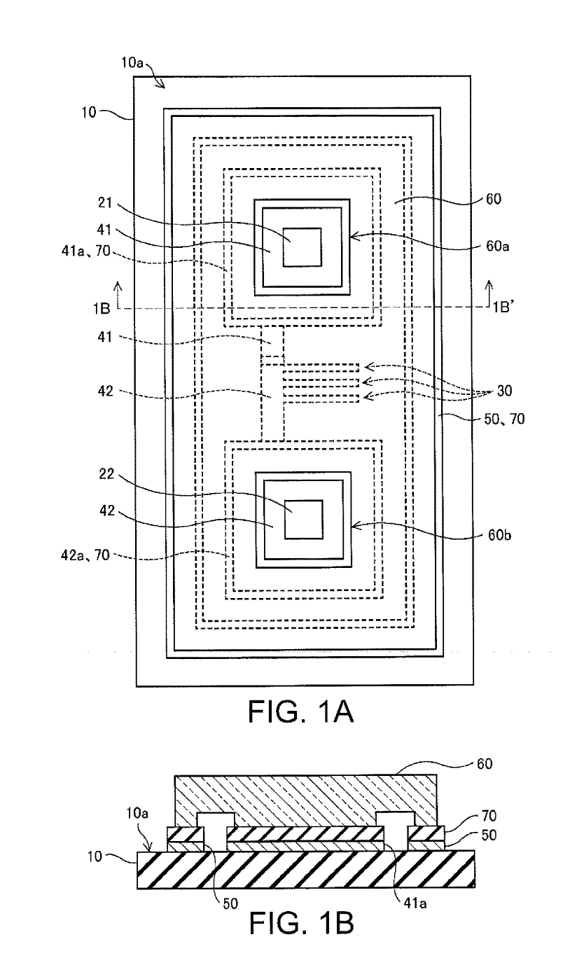

FIGS. 1A and 1B are diagrams showing a vibrator according to a first embodiment of the invention. FIG. 1A is a plan view, and FIG. B is a cross-sectional view taken along 1B-1B′ shown in FIG. 1A. As shown in FIGS. 1A and 1B, this vibrator includes a substrate 10, electrodes (pads) 21 and 22, a vibrating piece 30, interconnects 41 and 42, a joining portion 50, and a lid portion 60.

The substrate 10 is made of a semiconductor material such as silicon, for example. In that case, an insulating film made of silicon dioxide (SiO₂) or the like or an etching protective film made of silicon nitride (Si₃N₄) or the like may be provided on a main surface 10a of the substrate 10. The electrodes 21 and 22 are made of a conductive material such as aluminum (Al) or copper (Cu), for example, and are located on the substrate 10.

Although a vibrating piece made of a piezoelectric material, a capacitance-type vibrating piece, or the like can be used as the vibrating piece 30, a case where a vibrating piece made of a piezoelectric material is used will be described in the following embodiments. Examples of the piezoelectric material includes aluminum nitride (AlN), zinc oxide (ZnO), and PZT (Pb (lead) zirconate titanate). The vibrating piece 30 has a first surface (a lower surface in FIGS. 1A and 1B) and a second surface (an upper surface in FIGS. 1A and 1B) that face each other, and when voltage is applied between interconnects disposed on these surfaces, the vibrating piece 30 expands and contracts due to the applied voltage.

The interconnects 41 and 42 are made of a conductive material such as aluminum (Al) or copper (Cu), for example. The interconnect 41 includes a joining portion 41a surrounding the electrode 21 on the substrate 10 and is connected to the vibrating piece 30 and electrically connected to the electrode 21. The interconnect 42 includes a joining portion 42a surrounding the electrode 22 on the substrate 10 and is connected to the vibrating piece 30 and electrically connected to the electrode 22. A piezoelectric vibrating element that vibrates due to an alternating voltage being applied is constituted by the vibrating piece 30 and a portion of the interconnects 41 and 42.

The joining portion 50 is made of the same material as that of the interconnects 41 and 42, and is located on the substrate 10 so as to surround the vibrating piece 30 and the electrodes 21 and 22 at a distance from the vibrating piece 30 and the electrodes 21 and 22.

The lid portion 60 is made of glass, silicon, or the like, for example, and has openings 60a and 60b for exposing the electrodes 21 and 22 and is joined to the joining portions 41a, 42a, and 50 so as to seal the vibrating piece 30.

According to the present embodiment, the interconnect 41 including the joining portion 41a that surrounds the electrode 21 for external connection on the substrate 10, and the interconnect 42 including the joining portion 42a that surrounds the electrode 22 for external connection on the substrate 10 are provided, and the lid portion 60 is joined to the joining portions 41a and 42a. Thus, the influence of a level difference caused by the interconnect provided to connect the piezoelectric vibrating element to an external circuit on the joining reliability of the lid portion 60 can be reduced, and the joining reliability of the lid portion 60 can be improved. Also, the lid portion 60 is joined to the joining portions 41a, 42a, and 50 by providing the joining portion 50, and thus the vibrating piece 30 can be sealed,

As shown in FIGS. 1A and 1B, the vibrator may further include a joining film 70 located on at least the joining portions 41a, 42a, and 50. In that case, the lid portion 60 is joined to the joining portions 41a, 42a, and 50 via the joining film 70. The joining film 70 is made of an insulating material such as silicon dioxide (SiO₂), for example. The joining reliability of the lid portion 60 can be further increased by providing the joining film 70.

One of the interconnect 41 and the interconnect 42 may be integrated with the joining portion 50 in the present embodiment and other embodiments. Furthermore, if the interconnect integrated with the joining portion 50 is provided over a range wider that exceeds the region in which the lid portion 60 is joined, one of the electrode 21 and the electrode 22 and the configuration relating thereto may be omitted.

### Manufacturing Method 1

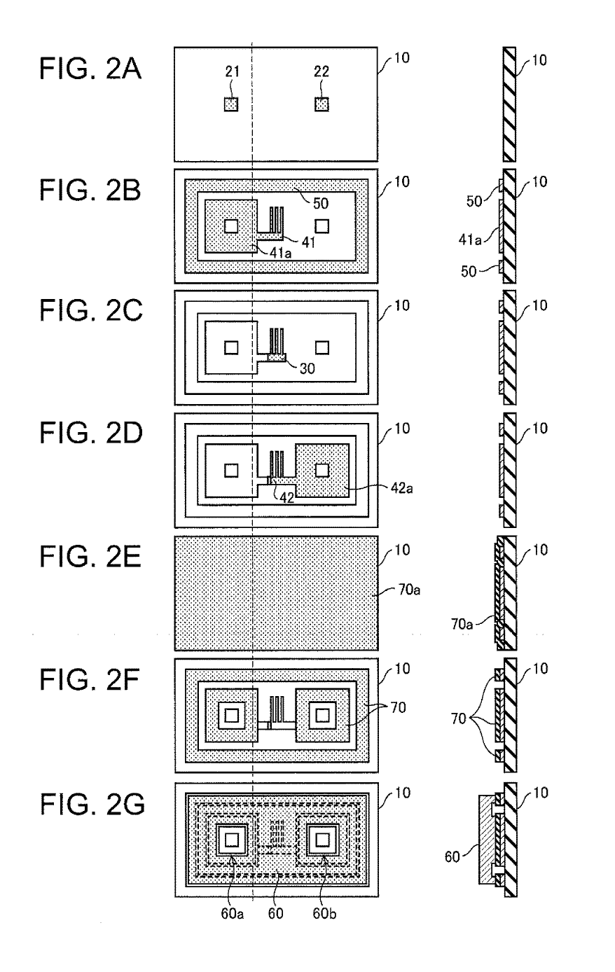

A method for manufacturing the vibrator shown in FIGS. 1A and 1B will be described with reference to FIGS. 2A to 2G.

FIGS. 2A to 2G are process diagrams for illustrating the method for manufacturing the vibrator according to the first embodiment of the invention. In FIGS. 2A to 2G, the left side shows plan views and the right side shows cross-sectional views taken along the broken line shown in the plan views, but lines that show the background of the cross-sections are omitted.

First, as shown in FIG. 2A, the electrodes 21 and 22 are formed on the substrate 10 by, for example, forming a conductive film by sputtering on the substrate 10 constituted by a silicone single crystal or the like, providing a resist by photolithography, and forming a pattern by dry etching.

Next, as shown in FIG. 2B, the interconnect 41 and the joining portion 50 are formed on the substrate 10 by forming the pattern of a conductive film by sputtering on the substrate 10 on which the electrodes 21 and 22 are formed. The interconnect 41 includes the joining portion 41a surrounding the electrode 21 on the substrate 10, and is electrically connected to the electrode 21. The joining portion 50 is formed so as to surround the electrodes 21 and 22 at a distance from the electrodes 21 and 22.

Next, as shown in FIG. 2C, the vibrating piece 30 that is connected to the interconnect 41 is formed, by forming the pattern of a piezoelectric film by sputtering on the substrate 10 on which the interconnect 41 and the like are formed.

Next, as shown in FIG. 2D, the interconnect 42 is formed by forming the pattern of a conductive film by sputtering on the substrate 10 on which the vibrating piece 30 and the like are formed. The interconnect 42 includes the joining portion 42a surrounding the electrode 22 on the substrate 10 and is connected to the vibrating piece 30 and electrically connected to the electrode 22.

Next, as shown in FIG. 2E, the joining film 70a may be formed by plasma CVD (chemical vapor deposition) on the substrate 10 on which the interconnect 42 and the like are formed. In that case, as shown in FIG. 2F, the joining film 70 located on at least the joining portions 41a, 42a, and 50 is formed by providing a resist by photolithography and forming a pattern by dry etching.

Next, as shown in FIG. 2G, the lid portion 60 having the openings 60a and 60b for exposing the electrodes 21 and 22 is joined to the joining portions 41a, 42a, and 50, and thereby the vibrating piece 30 is sealed. If the joining film 70 is formed, the lid portion 60 is joined to the joining portions 41a, 42a, and 50 via the joining film 70.

As described above, by making the thicknesses of the joining portions 41a, 42a, and 50 substantially equal to each other, a level difference caused by the joining portions 41a, 42a, and 50 does not occur, and thus the joining reliability of the lid portion 60 can be improved. Also, a process of flattening the joining film 70a by CMP (chemical mechanical polishing) and reducing the thickness of the joining film 70a by etchback is not required.

### Second Embodiment

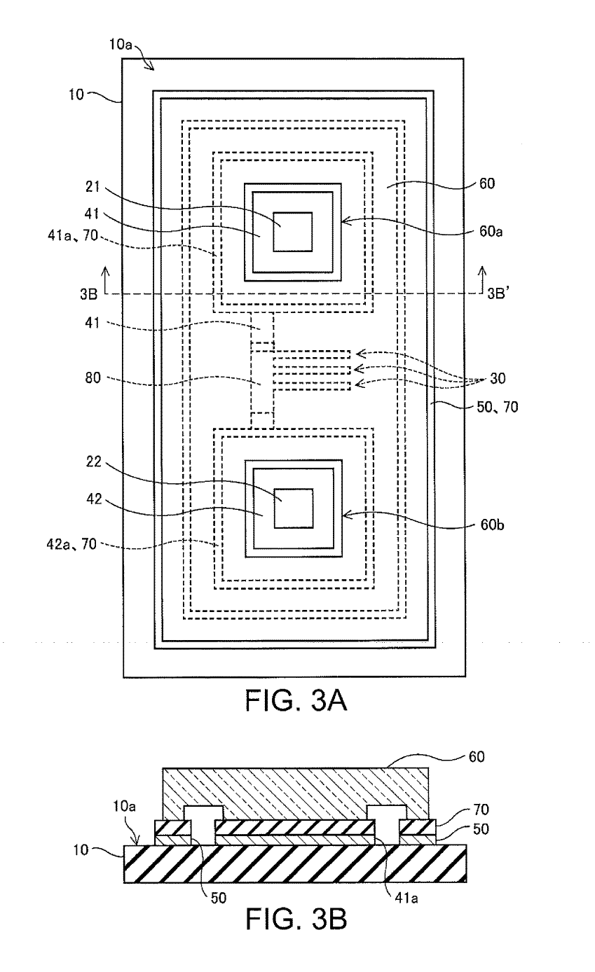

FIGS. 3A and 3B are diagrams showing a vibrator according to a second embodiment of the invention. FIG. 3A is a plan view, and FIG. 3B is a cross-sectional view taken along 3B-3B′ shown in FIG. 3A. In the second embodiment, the interconnect 42 is electrically connected to the electrode 22 but is not connected to the vibrating piece 30. Instead, the vibrator according to the second embodiment includes a conductive film 80 that is connected to the vibrating piece 30 and electrically connected to the interconnect 42. With regard to the other aspects, the second embodiment is similar to the first embodiment.

As shown in FIGS. 3A and 3B, this vibrator includes a substrate 10, electrodes (pads) 21 and 22, a vibrating piece 30, interconnects 41 and 42, a joining portion 50, a lid portion 60, and a conductive film 80. The interconnect 41 includes a joining portion 41a surrounding the electrode 21 on the substrate 10 and is connected to the vibrating piece 30 and electrically connected to the electrode 21. The interconnect 42 includes a joining portion 42a surrounding the electrode 22 on the substrate 10, and is electrically connected to the electrode 22.

The joining portion 50 is made of the same material as that of the interconnects 41 and 42, and is located on the substrate 10 so as to surround the vibrating piece 30 and the electrodes 21 and 22 at a distance from the vibrating piece 30 and the electrodes 21 and 22.

The conductive film 80 is made of a conductive material such as aluminum (Al), copper (Cu), or the like, for example, and is connected to the vibrating piece 30 and electrically connected to the interconnect 42. A piezoelectric vibrating element that vibrates due to an alternating voltage being applied is constituted by the vibrating piece 30 and a portion of the interconnect 41 and the conductive film 80.

The lid portion 60 has openings 60a and 60b for exposing the electrodes 21 and 22 and is joined to the joining portions 41a, 42a, and 50 so as to seal the vibrating piece 30. As shown in FIGS. 3A and 3B, the vibrator may further include a joining film 70 located on at least the joining portions 41a, 42a, and 50. In that case, the lid portion 60 is joined to the joining portions 41a, 42a, and 50 via the joining film 70.

According to the second embodiment, since the joining portions 41a, 42a, and 50 to which the lid portion 60 is joined can be formed simultaneously, the influence of a level difference caused by the interconnects on the joining reliability of the lid portion 60 can be reduced by making heights of the joining portions 41a, 42a, and 50 equal to each other, and thus the joining reliability of the lid portion 60 can be improved.

### Manufacturing Method 2

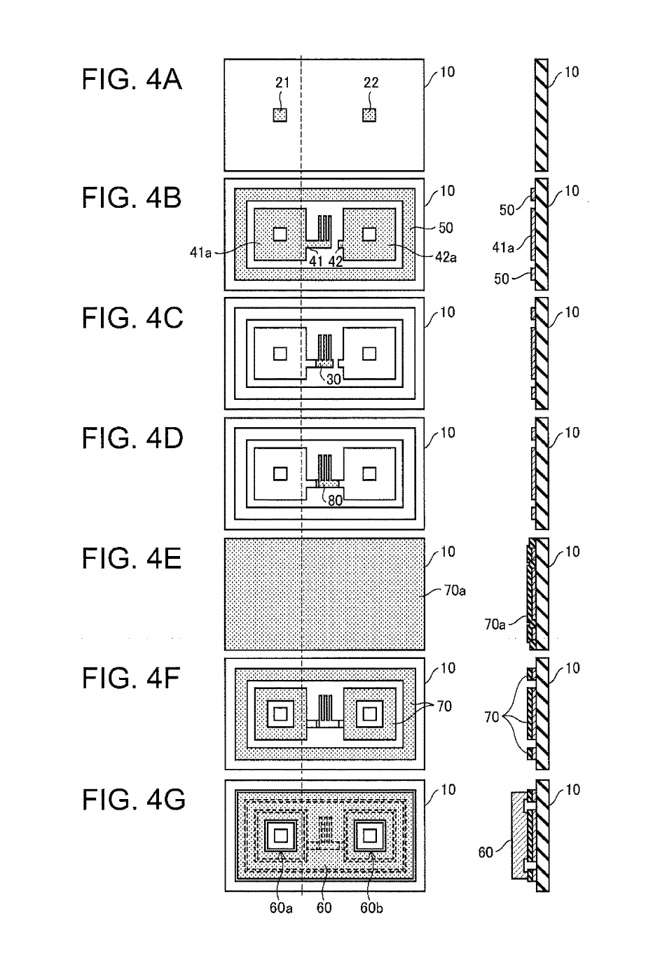

FIGS. 4A to 4G are process diagrams for illustrating the method for manufacturing the vibrator according to the second embodiment of the invention. In FIGS. 4A to 4G, the left side shows plan views and the right side shows cross-sectional views taken along the broken line shown in the plan views, but lines that show the background of the cross-sections are omitted.

First, as shown in FIG. 4A, the electrodes 21 and 22 are formed on the substrate 10 by, for example, forming a conductive film by sputtering on the substrate 10 constituted by a silicone single crystal or the like, providing a resist by photolithography, and forming a pattern by dry etching.

Next, as shown in FIG. 4B, the interconnects 41 and 42 and the joining portion 50 are formed on the substrate 10 by forming the pattern of a conductive film by sputtering on the substrate 10 on which the electrodes 21 and 22 are formed. The interconnect 41 includes the joining portion 41a surrounding the electrode 21 on the substrate 10, and is electrically connected to the electrode 21. The interconnect 42 includes the joining portion 42a surrounding the electrode 22 on the substrate 10, and is electrically connected to the electrode 22. The joining portion 50 is formed so as to surround the electrodes 21 and 22 at a distance from the electrodes 21 and 22.

Next, as shown in FIG. 4C, the vibrating piece 30 that is connected to the interconnect 41 is formed by forming the pattern of a piezoelectric film by sputtering on the substrate 10 on which the interconnects 41 and 42, and the like are formed.

Next, as shown in FIG. 4D, the conductive film 80 is formed by forming the pattern of a conductive film by sputtering on the substrate 10 on which the vibrating piece 30 and the like are formed. The conductive film 80 is connected to the vibrating piece 30 and electrically connected to the interconnect 42.

Next, as shown in FIG. 4E, a joining film 70a may be formed by plasma CVD on the substrate 10 on which the conductive film 80 and the like are formed. In that case, as shown in FIG. 4F, the joining film 70 located on at least the joining portions 41a, 42a, and 50 is formed by providing a resist by photolithography and forming a pattern by dry etching.

Next, as shown in FIG. 4G, the lid portion 60 having the openings 60a and 60b for exposing the electrodes 21 and 22 is joined to the joining portions 41a, 42a, and 50, and thereby the vibrating piece 30 is sealed. If the joining film 70 is formed, the lid portion 60 is joined to the joining portions 41a, 42a, and 50 via the joining film 70.

As described above, since the joining portions 41a, 42a, and 50 to which the lid portion 60 is joined have been formed simultaneously, the heights of the joining portions 41a, 42a, and 50 can be made equal to each other, and thus the joining reliability of the lid portion 60 can be improved. Also, a process of flattening the joining film 70a by CMP and reducing the thickness of the joining film 70a by etchback is not required.

### Third Embodiment

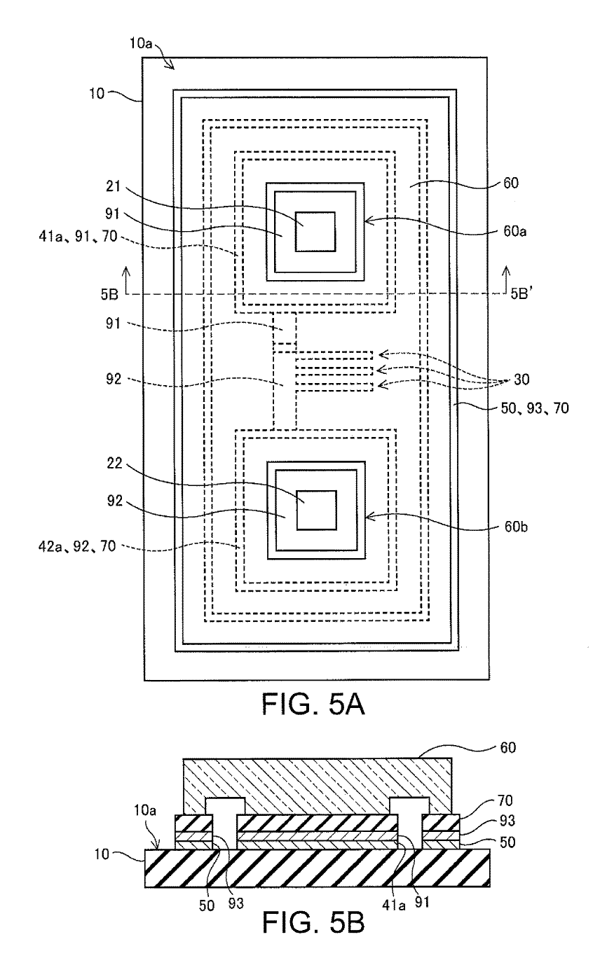

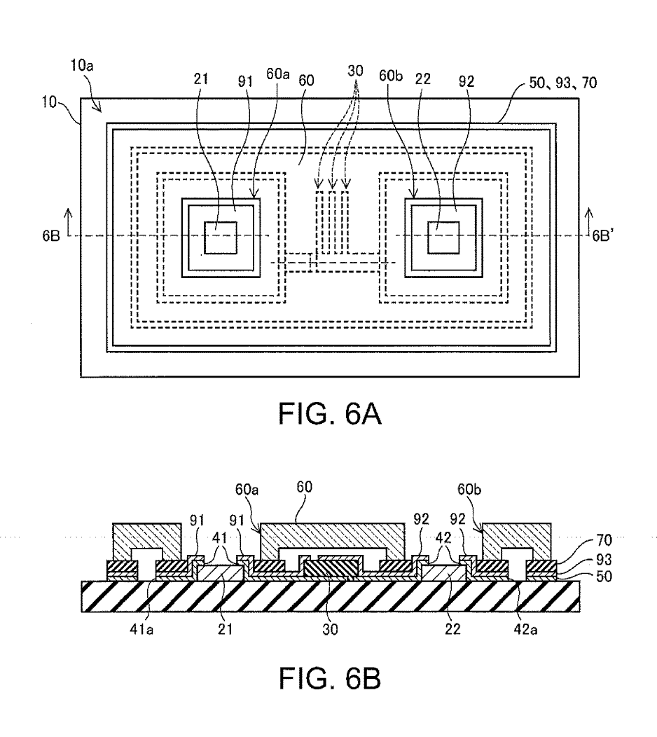

FIGS. 5A, 5B, 6A, and 6B are diagrams showing a vibrator according to a third embodiment of the invention. FIGS. 5A and 6A are plan views, FIG. 5B is a cross-sectional view taken along 5B-5B′ shown in FIG. 5A, and FIG. 6B is a cross-sectional view taken along 6B-6B′ shown in FIG. 6A.

In the third embodiment, the interconnect 42 is electrically connected to the electrode 22 but is not connected to the vibrating piece 30. Instead, the vibrator according to the third embodiment includes a conductive layer that includes a conductive film 91 located on at least the joining portion 41a, a conductive film 92 that is connected to the vibrating piece 30 and is located on at least the joining portion 42a, and a conductive film 93 located on at least the joining portion 50. With regard to the other aspects, the third embodiment is similar to the first or second embodiment.

As shown in FIGS. 5A, 5B, 6A, and 6B, this vibrator includes the substrate 10, the electrodes (pads) 21 and 22, the vibrating piece 30, the interconnects 41 and 42, the joining portion 50, the lid portion 60, and conductive layers (conductive films 91 to 93). The interconnect 41 includes a joining portion 41a surrounding the electrode 21 on the substrate 10 and is connected to the vibrating piece 30 and electrically connected to the electrode 21. The interconnect 42 includes the joining portion 42a surrounding the electrode 22 on the substrate 10, and is electrically connected to the electrode 22.

The joining portion 50 is made of the same material as that of the interconnects 41 and 42, and is located on the substrate 10 so as to surround the vibrating piece 30 and the electrodes 21 and 22 at a distance from the vibrating piece 30 and the electrodes 21 and 22.

The conductive layers including the conductive films 91 to 93 are made of a conductive material such as aluminum (Al) or copper (Cu), for example. The conductive film 91 is located on at least the joining portion 41a. The conductive film 92 is connected to the vibrating piece 30 and is located on at least the joining portion 42a. A piezoelectric vibrating element that vibrates due to an alternating voltage being applied is constituted by the vibrating piece 30 and a portion of the interconnect 41 and the conductive film 92. The conductive film 93 is located on at least the joining portion 50a.

If the vibrator includes two electrodes 21 and 22, two interconnects 41 and 42 that respectively include the joining portions 41a and 42a surrounding the electrodes, and the conductive films 91 and 92 that are respectively located on at least the joining portions 41a and 42a in this manner, the joining reliability of the lid portion 60 can be improved by making the heights of the joining portions 41a and 42a equal to each other by the conductive films 91 and 92.

The lid portion 60 has openings 60a and 60b for exposing the electrodes 21 and 22 and is joined to the joining portions 41a, 42a, and 50 so as to seal the vibrating piece 30. As shown in FIGS. 5A, 5B, 6A, and 6B, the vibrator may further include a joining film 70 located on at least the joining portions 41a, 42a, and 50. In that case, the lid portion 60 is joined to the joining portions 41a, 42a, and 50 via the joining film 70.

According to the third embodiment, since the joining portions 41a, 42a, and 50 to which the lid portion 60 is joined can be formed simultaneously and then the conductive films 91 to 93 can be formed thereon simultaneously, the influence of a level difference caused by the interconnects on the joining reliability of the lid portion 60 can be reduced by making heights of the conductive films 91 to 93 equal to each other, and thus the joining reliability of the lid portion 60 can be improved.

### Manufacturing Method 3

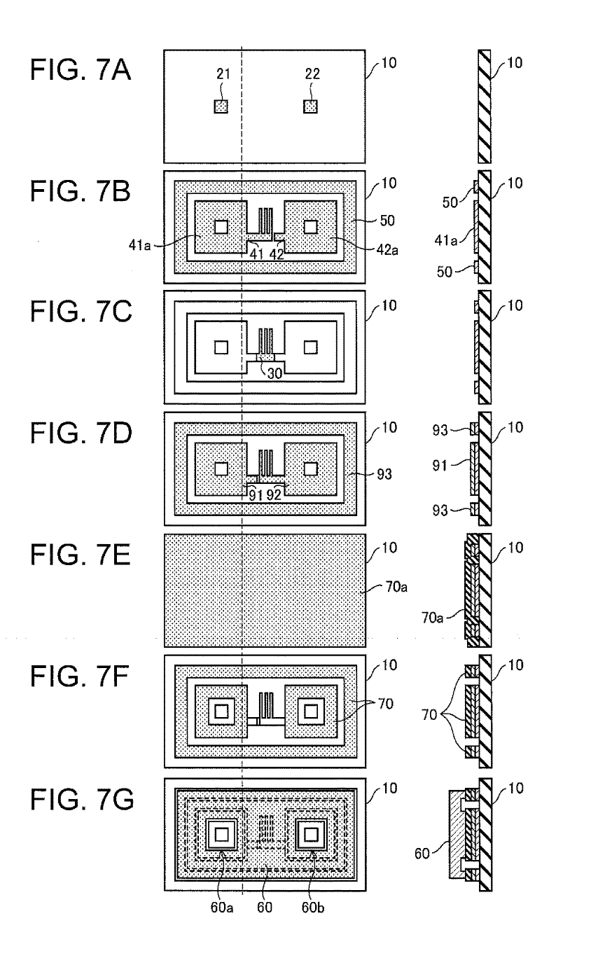

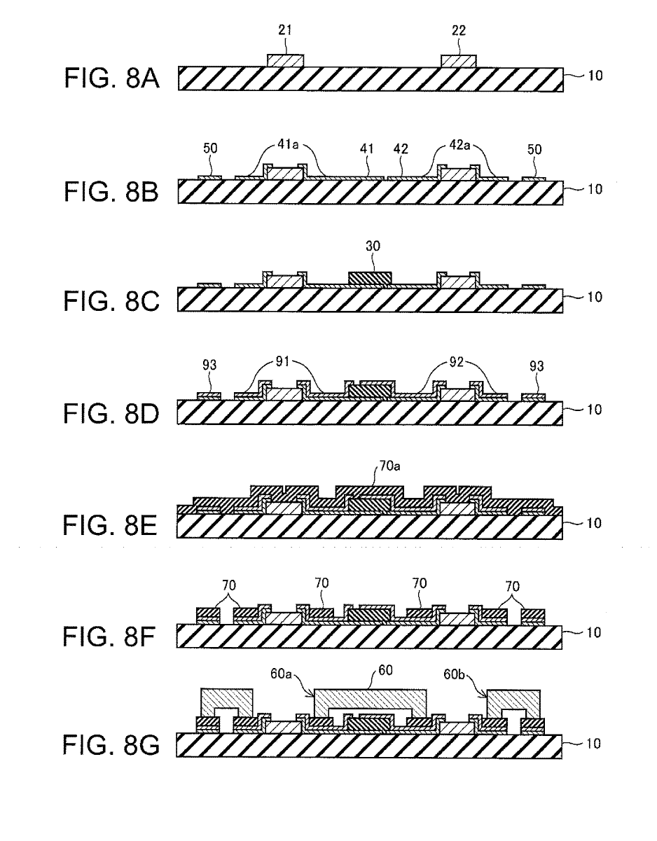

FIGS. 7A to 7G and 8A to 8G are process diagrams for illustrating the method for manufacturing the vibrator according to the third embodiment of the invention. In FIGS. 7A to 7G, the left side shows plan views and the right side shows cross-sectional views taken along the broken line shown in the plan views, but lines that show the background of the cross-sections are omitted. FIGS. 8A to 8G are cross-sectional views taken along 6B-6B′ shown in FIG. 6A, but lines that show the background of the cross-sections are omitted.

First, as shown in FIGS. 7A and 8A, the electrodes 21 and 22 are formed on the substrate 10 by, for example, forming a conductive film by sputtering on the substrate 10 constituted by a silicone single crystal or the like, providing a resist by photolithography, and forming a pattern by dry etching.

Next, as shown in FIGS. 7B and 8B, the interconnects 41 and 42 and the joining portion 50 are formed on the substrate 10 by forming the pattern of conductive films by sputtering on the substrate 10 on which the electrodes 21 and 22, and the like are formed. The interconnect 41 includes the joining portion 41a surrounding the electrode 21 on the substrate 10, and is electrically connected to the electrode 21. The interconnect 42 includes the joining portion 42a surrounding the electrode 22 on the substrate 10, and is electrically connected to the electrode 22. The joining portion 50 is formed so as to surround the electrodes 21 and 22 at a distance from the electrodes 21 and 22.

Next, as shown in FIGS. 7C and 8C, the vibrating piece 30 that is connected to the interconnect 41 is formed by forming the pattern of a piezoelectric film by sputtering on the substrate 10 on which the interconnects 41 and 42, and the like are formed.

Next, as shown in FIGS. 7D and 8D, a conductive layer including the conductive films 91 to 93 is formed by forming the pattern of the conductive films by sputtering on the substrate 10 on which the vibrating piece 30 and the like are formed. The conductive film 91 is located on at least the joining portion 41a, the conductive film 92 is connected to the vibrating piece 30 and is located on at least the joining portion 42a. Also, the conductive film 93 is located on at least the joining portion 50.

Next, as shown in FIGS. 7E and 8E, a joining film 70a may be formed by plasma CVD on the substrate 10 on which the conductive films 91 to 93 and the like are formed. In that case, as shown in FIG. 7F and FIG. 8F, the joining film 70 located on at least the joining portions 41a, 42a, and 50 is formed by providing a resist by photolithography and forming a pattern by dry etching.

Next, as shown in FIGS. 7G and 8G, the lid portion 60 having openings 60a and 60b for exposing the electrodes 21 and 22 is joined to the joining portions 41a, 42a, and 50, and thereby the vibrating piece 30 is sealed. If the joining film 70 is formed, the lid portion 60 is joined to the joining portions 41a, 42a, and 50 via the joining film 70.

As described above, since the conductive films 91 to 93 are also formed simultaneously after the joining portions 41a, 42a, and 50 to which the lid portion 60 is joined have been formed simultaneously, the heights of the conductive films 91 to 93 can be made equal to each other, and thus the joining reliability of the lid portion 60 can be improved. Also, a process of flattening the joining film 70a by CMP and reducing the thickness of the joining film 70a by etchback is not required.

### Fourth Embodiment

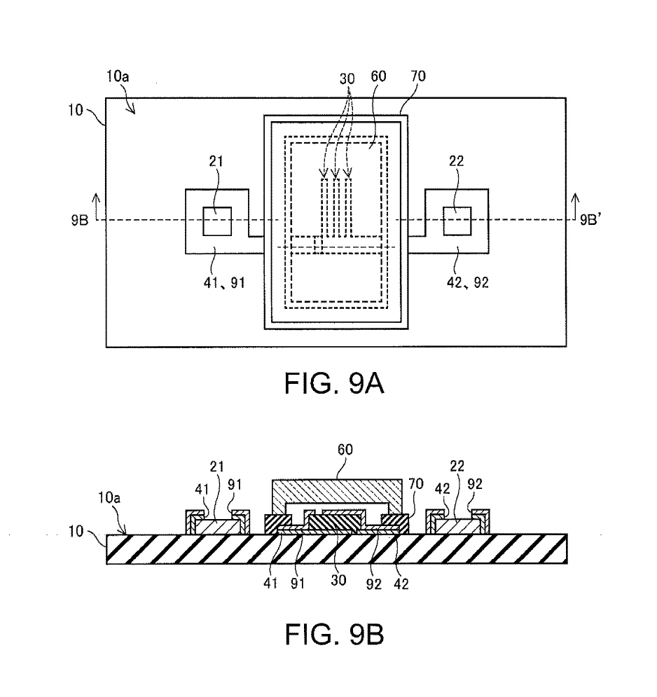

FIGS. 9A and 9B are diagrams showing a vibrator according to a fourth embodiment of the invention. FIG. 9A is a plan view, and FIG. 9B is a cross-sectional view taken along 9B-9B′ shown in FIG. 9A. In the fourth embodiment, although a level difference with the main surface 10a of the substrate 10 occurs in a region in which the lid portion 60 is joined due to the interconnects 41 and 42 and the conductive films 91 and 92, the level difference is eliminated by the joining film 70 provided thereon. With regard to the material and the like of each portion, the fourth embodiment is similar to the first to third embodiments.

As shown in FIGS. 9A and 9B, this vibrator includes the substrate 10, the electrodes (pads) 21 and 22, the vibrating piece 30, the interconnects 41 and 42, the joining portion 50, the lid portion 60, the joining film 70, and conductive layers (conductive films 91 and 92). The interconnect 41 is provided on the substrate 10 and is connected to the vibrating piece 30 and electrically connected to the electrode 21. The interconnect 42 is provided on the substrate 10 and is electrically connected to the electrode 22.

The conductive film 91 is located on at least the interconnect 41. The conductive film 92 is connected to the vibrating piece 30 and is located on at least the interconnect 42. A piezoelectric vibrating element that vibrates due to an alternating voltage being applied is constituted by the vibrating piece 30 and a portion of the interconnect 41 and the conductive film 92. The lid portion 60 has openings 60a and 60b for exposing the electrodes 21 and 22 and is joined to the joining portions 41a, 42a, and 50 so as to seal the vibrating piece 30.

According to the fourth embodiment, since the level difference occurring on the main surface 10a of the substrate 10 due to the interconnects 41 and 42 and the conductive films 91 and 92 is eliminated by the joining film 70 provided thereon, the joining reliability of the lid portion 60 can be improved. Also, openings do not need to be provided in the lid portion 60, and thus the structure of the lid portion 60 is simplified.

### Manufacturing Method 4

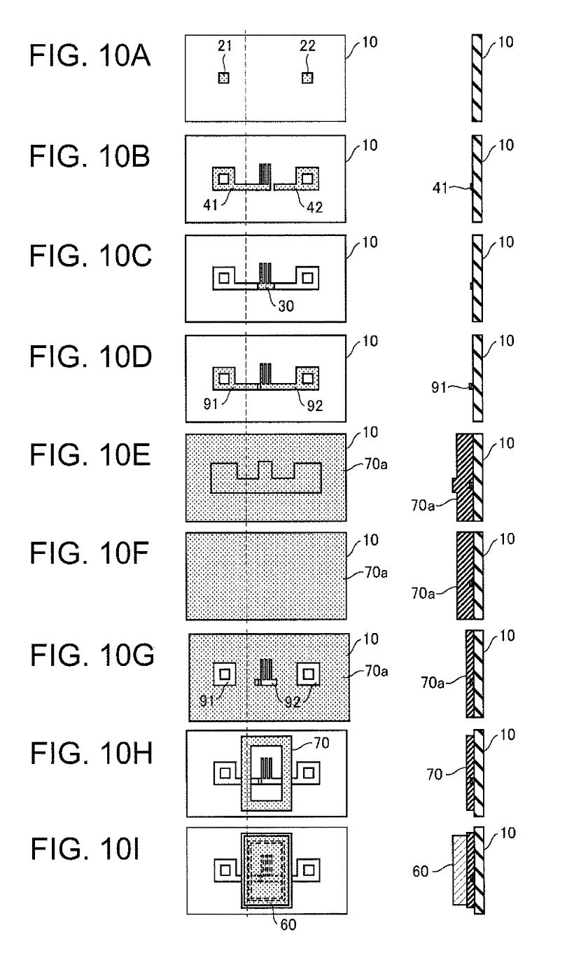

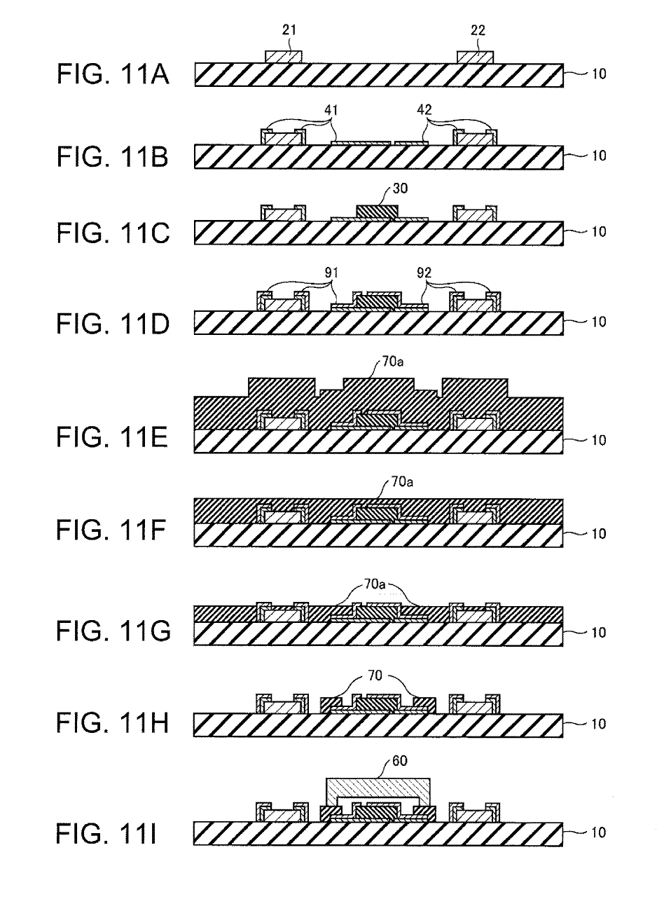

FIGS. 10A to 10I and 11A to 11I are process diagrams for illustrating the method for manufacturing the vibrator according to the fourth embodiment of the invention. In FIGS. 10A to 10I, the left side shows plan views and the right side shows cross-sectional views taken along the broken line shown in the plan views, but lines that show the background of the cross-sections are omitted. FIGS. 11A to 11I are cross-sectional views taken along 9B-9B′ shown in FIG. 9A, but lines that show the background of the cross-sections are omitted.

First, as shown in FIGS. 10A and 11A, the electrodes 21 and 22 are formed on the substrate 10 by, for example, forming a conductive film by sputtering on the substrate 10 constituted by a silicone single crystal or the like, providing a resist by photolithography, and forming a pattern by dry etching.

Next, as shown in FIGS. 10B and 11B, the interconnects 41 and 42 are formed on the substrate 10 by forming the pattern of conductive films by sputtering on the substrate 10 on which the electrodes 21 and 22 are formed. The interconnect 41 is electrically connected to the electrode 21. The interconnect 42 is electrically connected to the electrode 22.

Next, as shown in FIGS. 10C and 11C, the vibrating piece 30 that is connected to the interconnect 41 is formed by forming the pattern of a piezoelectric film by sputtering on the substrate 10 on which the interconnects 41 and 42, and the like are formed.

Next, as shown in FIGS. 10D and 11D, a conductive layer including the conductive films 91 and 92 is formed by forming the pattern of conductive films by sputtering on the substrate 10 on which the vibrating piece 30 and the like are formed. The conductive film 91 is located on at least the interconnect 41, and the conductive film 92 is connected to the vibrating piece 30 and is located on at least the interconnect 42.

Next, as shown in FIGS. 10E and 11E, the joining film 70a is formed by plasma CVD on the substrate 10 on which the conductive films 91 to 93 and the like are formed. As shown in FIGS. 10F and 11F, the joining film 70a is flattened by CMP. Accordingly, a level difference occurring on the main surface of the substrate 10 due to the interconnects 41 and 42 and the conductive films 91 and 92 is eliminated. Furthermore, as shown in FIGS. 10G and 11G, a portion of the conductive films 91 and 92 are exposed by reducing the thickness of the joining film 70a by etchback.

Next, as shown in FIGS. 10H and 11H, the joining film 70 is formed in a region in which the lid portion 60 is joined, by providing a resist by photolithography and forming a pattern by dry etching. Next, as shown in FIGS. 10I and 11I, the vibrating piece 30 is sealed by joining the lid portion 60 to the substrate 10 via at least the joining film 70. As described above, since the joining film 70 to which the lid portion 60 is joined is flattened, the joining reliability of the lid portion 60 can be improved.

### Oscillator

Next, an oscillator in which a vibrator according to the embodiments of the invention is used will be described.

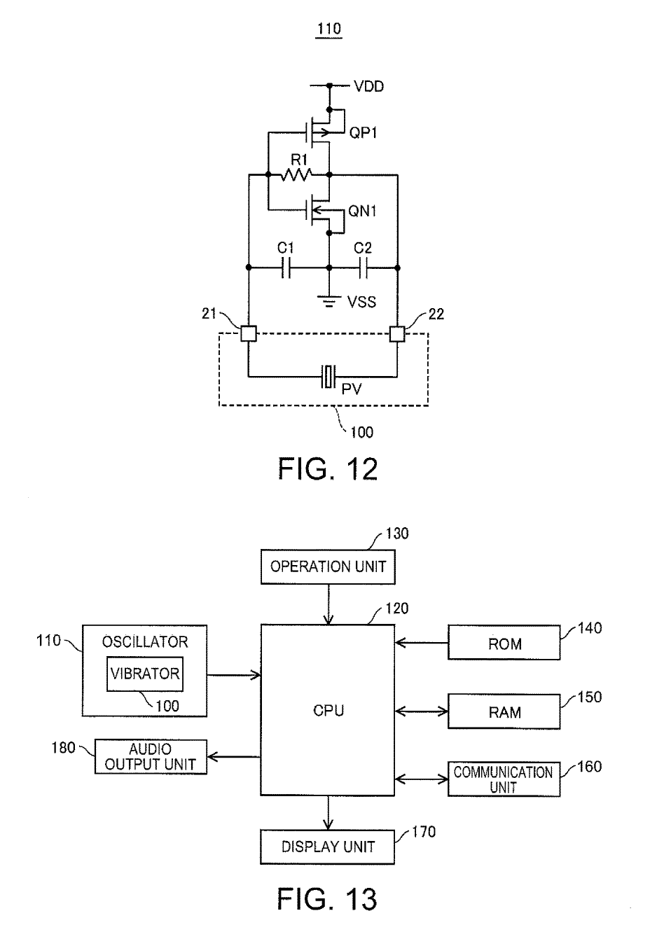

FIG. 12 is a circuit diagram showing a configuration example of an oscillator according to an embodiment of the invention. FIG. 12 shows a piezoelectric vibrating element PV formed in a vibrator 100 according to the embodiments of the invention, and electrodes 21 and 22 for connecting the piezoelectric vibrating element PV to an external circuit. An oscillator 110 according to an embodiment of the invention includes, in addition thereto, a P-channel MOS transistor QP1, an N-channel MOS transistor QN1, a feedback resistor R1, and capacitors C1 and C2.

A power supply potential VDD on the high potential side is supplied to a source of the transistor QP1, a power supply potential VSS on the low potential side is supplied to a source of the transistor QN1, and the transistors QP1 and QN1 constitutes an inverter. Gates of the transistors QP1 and QN1, which serve as input terminals of the inverter, are connected to the electrode 21, and Drains of the transistors QP1 and QN1, which serve as the output terminals of the inverter, are connected to the electrode 22.

The capacitor C1 is connected between the input terminal of the inverter and the interconnect of the power supply potential VSS, and the capacitor C2 is connected between the output terminal of the inverter and the interconnect of the power supply potential VSS. The piezoelectric vibrating element PV and a feedback resistor R1 are connected in parallel between the input terminal and the output terminal of the inverter.

The inverter performs an inverting amplification operation, and a signal output from the output terminal is fed back to the input terminal via the piezoelectric vibrating element PV and the feedback resistor R1. At that time, the piezoelectric vibrating element PV vibrates due to an alternating voltage applied by the inverter. This vibration is greatly excited at a specific resonance frequency, and the piezoelectric vibrating element PV operates as a negative resistor. As a result, the oscillator 110 oscillates at an oscillation frequency mainly determined by the resonance frequency of the piezoelectric vibrating element PV.

According to the present embodiment, it is possible to provide a stable oscillator 110 having a small change in the oscillation frequency over time, using the vibrator 100 having improved joining reliability of the lid portion that constitutes the sealing structure. Note that a transistor, a resistor, and the like that constitutes the oscillator 110 may be integrally fabricated on the substrate 10 shown in FIGS. 1A and 1B and the like, using a semiconductor manufacturing process.

### Electronic Device

Next, an electronic device in which a vibrator according to the embodiments of the invention is used will be described.

FIG. 13 is a block diagram showing a first configuration example of an electronic device according to an embodiment of the invention. As shown in FIG. 13, this electronic device includes the oscillator 110 in which the vibrator 100 according to the embodiments of the invention is used, and may also include a CPU 120, an operation unit 130, a ROM (read only memory) 140, a RAM (random access memory) 150, a communication unit 160, a display unit 170, and an audio output unit 180. Note that a portion of the constituent elements shown in FIG. 13 may be omitted or modified, and alternatively, other constituent elements may be added to the constituent elements shown in FIG. 13.

The oscillator 110 includes the vibrator 100 in which a piezoelectric vibrating element is formed, and generates a clock signal due to oscillation at an oscillation frequency mainly determined by the resonance frequency of the piezoelectric vibrating element. The clock signal generated by the oscillator 110 is supplied to the components of the electronic device via the CPU 120 and the like.

The CPU 120 operates in synchronization with the clock signal supplied from the oscillator 110, and performs various types of signal processing and control processing in accordance with programs stored in the ROM 140 and the like. For example, the CPU 120 performs various types of data processing in response to an operation signal supplied from the operation unit 130, and controls the communication unit 160 for performing data communication with an external portion. Alternatively, the CPU 120 generates an image signal for causing the display unit 170 to display various images, and generates an audio signal for causing the audio output unit 180 to output various audio.

The operation unit 130 is an input apparatus including an operation key, a button switch, and the like, for example, and outputs operation signals corresponding to operations performed by a user to the CPU 120. The ROM 140 stores programs, data, and the like for the CPU 120 performing various types of computational processing and control processing. Also, the RAM 150 is used as a working area for the CPU 120, and temporarily stores programs and data that are read out from the ROM 140, data input using the operation unit 130, the results of computational calculations that the CPU 120 executes in accordance with the programs, and the like.

The communication unit 160 is constituted by an analog circuit and a digital circuit, for example, and performs data communication between the CPU 120 and an external apparatus. The display unit 170 includes a LCD (liquid crystal display apparatus) and the like, for example, and displays various types of information based on display signals supplied from the CPU 120, Also, the audio output unit 180 includes a speaker and the like, and outputs audio based on audio signals supplied from the CPU 120, for example.

Examples of the above-described electronic device include a mobile terminal such as a mobile phone, a smart card, a calculator, an electronic dictionary, an electronic game device, a digital still camera, a digital movie camera, a television, a videophone, a security TV monitor, a head-mounted display, a personal computer, a printer, a network device, a car navigation device, a measurement device, and medical equipment (for example, an electronic thermometer, a sphygmomanometer, a glucometer, an electrocardiographic apparatus, ultrasound diagnostic equipment, and an electronic endoscope).

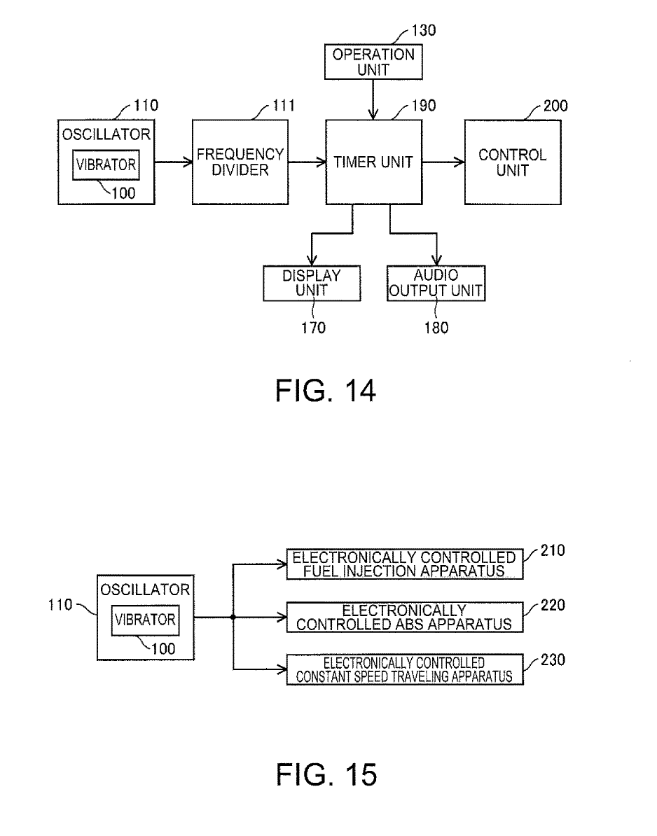

FIG. 14 is a block diagram showing a second configuration example of an electronic device according to an embodiment of the invention. In this example, a clock and a timer will be described. A clock according to an embodiment of the invention includes the oscillator 110 in which the vibrator 100 according to the embodiments of the invention is used, a frequency divider 111, an operation unit 130, a display unit 170, an audio output unit 180, and a timer unit 190. Also, a time according to an embodiment of the invention includes a control unit 200 instead of the audio output unit 180.

The frequency divider 111 is constituted by a plurality of flip flops, for example, and divides a clock signal supplied from the oscillator 110 to generate a divided clock signal for timing. The timer unit 190 is constituted by a counter and the like, for example, and performs a timing operation based on the divided clock signal supplied from the frequency divider 111, and generates an alarm signal for producing a display signal and an alarm for representing the current time and alarm time.

The operation unit 130 is used to set the current time and an alarm time in the timer unit 190. The display unit 170 displays the current time and the alarm time in accordance with a display signal supplied from the timer unit 190. The audio output unit 180 produces an alarm sound in accordance with an alarm signal supplied from the timer unit 190.

In the case of the timer, a timer function is provided instead of an alarm function. That is, the timer unit 190 generates a timer signal indicating that the current time matches a set time. The control unit 200 turns a device that is connected to the timer on and off in accordance with the time signal supplied from the timer unit 190.

According to the present embodiment, it is possible to provide an electronic device that operates in synchronization with a clock signal having a stable frequency obtained using the vibrator 100 having improved joining reliability of the lid portion that constitutes the sealing structure.

### Movable Body

Next, a movable body in which a vibrator according to the embodiments of the invention is used will be described. Examples of the movable body include a car, a self-propelled robot, a self-propelled transportation device, a train, a ship, an airplane, and a satellite.

FIG. 15 is a block diagram showing a configuration example of a movable body according to an embodiment of the invention. As shown in FIG. 15, this movable body includes the oscillator 110 in which the vibrator 100 according to the embodiments of the invention is used, and may be provided with various electronically controlled apparatuses such as an electronically controlled fuel injection apparatus 210, an electronically controlled ABS apparatus 220, and an electronically controlled constant speed traveling apparatus 230. Note that a portion of the constituent elements shown in FIG. 15 may be omitted or modified, and alternatively, other constituent elements may be added to the constituent elements shown in FIG. 15.

The oscillator 110 includes the vibrator 100 in which a piezoelectric vibrating element is formed, and generates a clock signal due to oscillation at an oscillation frequency mainly determined by the resonance frequency of the piezoelectric vibrating element. The clock signal generated by the oscillator 110 is supplied to the electronically controlled fuel injection apparatus 210, the electronically controlled ABS apparatus 220, the electronically controlled constant speed traveling apparatus 230, or the like.

The electronically controlled fuel injection apparatus 210 operates in synchronization with the clock signal supplied from the oscillator 110, and injects liquid fuel into inhaled air in the form of mist at a predetermined time, in a premixed combustion engine such as a gasoline engine. The electronically controlled ABS (antilock braking system) apparatus 220 operates in synchronization with the clock signal supplied from the oscillator 110, and when an operation is performed such that the brakes are applied, the brakes are gradually driven powerfully and when the movable body starts to slide, the brakes are repeatedly released and then driven again. The electronically controlled constant speed traveling apparatus 230 operates in synchronization with the clock signal supplied from the oscillator 110, and controls the accelerator, the brakes, and the like while monitoring the speed of the movable body such that the speed of the movable body is constant.

According to the present embodiment, it is possible to provide a movable body that operates in synchronization with a clock signal having a stable frequency obtained using the vibrator 100 having improved joining reliability of the lid portion that constitutes the sealing structure.

Although a vibrator provided with a piezoelectric vibrating element has been described in the above-described embodiments, the invention is not limited to the above-described embodiments. For example, the invention can be applied to a vibrator including an electrostatic capacitance-type vibrating element and the like. In this manner, the invention can be modified in many ways within the technical idea of the invention by a person having ordinary skill in the art.

The entire disclosure of Japanese Patent Application No. 2015-136695, filed Jul. 8, 2015 is expressly incorporated by reference herein.

What is claimed is:

1. A vibrator comprising:
a substrate;
a first electrode located on the substrate;
a vibrating piece;
a first interconnect that includes a first joining portion surrounding the first electrode on the substrate and is connected to the vibrating piece and electrically connected to the first electrode; and
a lid portion that has an opening for exposing the first electrode and is joined to the first joining portion.

2. The vibrator according to claim 1, further comprising:
a first conductive film that is located on at least the first joining portion.

3. The vibrator according to claim 1, further comprising:
a fourth joining portion that is located on the substrate so as to surround the vibrating piece and the first electrode at a distance from the vibrating piece and the electrode, and to which the lid portion is connected.

4. The vibrator according to claim 3, further comprising a joining film located on at least the first joining portion and the second joining portion, wherein
the lid portion is joined to the first joining portion and the fourth joining portion via at least the joining film.

5. The vibrator according to claim 1, further comprising:
a second electrode that are located on the substrate;
a second interconnect that includes a second joining portion surrounding the second electrode on the substrate and is electrically connected to the second electrode; and
a third joining portion that is located on the substrate so as to surround the vibrating piece and the first and second electrodes at a distance from the vibrating piece and the first and second electrodes, wherein
the lid portion that has an opening for exposing the first and second electrodes and is joined to the first to third joining portions.

6. The vibrator according to claim 5, wherein
the second interconnect is connected to the vibrating piece.

7. The vibrator according to claim 5, further comprising:
a second conductive film that is connected to the vibrating piece.

8. The vibrator according to claim 7, wherein
the second conductive film is electrically connected to the second interconnect.

9. The vibrator according to claim 7, further comprising:
a conductive layer that includes a first conductive film located on at least the first joining portion, the second conductive film connected to the vibrating piece and located on at least the second joining portion, and a third conductive film located on at least the third joining portion, wherein
the lid portion is joined to the first to third joining portions via at least the conductive layer.

10. An oscillator comprising the vibrator according to claim 1.

11. An electronic device comprising the vibrator according to claim 1.

12. A movable body comprising the vibrator according to claim 1.

13. A method for manufacturing a vibrator, comprising:
(a) forming a first electrode on a substrate;
(b) forming a first interconnect that includes a first joining portion surrounding the first electrode on the substrate and is electrically connected to the first electrode;
(c) forming a vibrating piece that is connected to the first interconnect; and
(d) joining a lid portion that has an opening for exposing the first electrode to the first joining portion.

14. The method for manufacturing a vibrator according to claim 13, further comprising:
(a1) forming a second electrode on a substrate;
(b1) forming, on the substrate, a second joining portion that surrounds the first and second electrodes at a distance from the first and second electrodes; and
(d2) forming a second interconnect that includes a third joining portion surrounding the second electrode on the substrate and is connected to the vibrating piece and electrically connected to the second electrode, wherein
the lid portion has the opening for exposing the first and second electrodes and joined to the first to third joining portions,

15. The method for manufacturing a vibrator according to claim 13, further comprising:
(a2) forming the second electrode on a substrate;
(b2) forming, on the substrate, a second interconnect that includes the second joining portion surrounding the second electrode and is electrically connected to the second electrode and a third joining portion that surrounds the first and second electrodes at a distance from the first and second electrodes; and
(d2) forming a conductive film that is connected to the vibrating piece and is electrically connected to the second interconnect, wherein
the lid portion has the opening for exposing the first and second electrodes and joined to the first to third joining portions.

16. The method for manufacturing a vibrator according to claim 13, further comprising:
(a3) forming the second electrode on a substrate;
(b) forming, on the substrate, the second interconnect that includes the second joining portion surrounding the second electrode and is electrically connected to the second electrode, and a third joining portion that surrounds the first and second electrodes at a distance from the first and second electrodes; and
(d3) forming a conductive layer that includes a first conductive film located on at least the first joining portion, a second conductive film that is connected to the vibrating piece and is located on at least the second joining portion, and a third conductive film located on at least the third joining portion, wherein
the lid portion has the opening for exposing the first and second electrodes and joined to the first to third joining portions via at least the conductive layer.
